(19) United States
(12) Patent Application Publication
(10) Pub. No.: US 2005/0141657 A1
(43) Pub. Date: Jun. 30, 2005

(54) Adaptive channel equalizer for wireless system

(76) Inventors: Alexander A. Maltsev, Nizhny Novgorod (RU); Ali S. Sadri, San Diego, CA (US); Andrey V. Pudeyev, Nizhny Novgorod (RU); Alexey E. Rubtsov, Nizhny Novgorod (RU)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/750,064

(22) Filed: Dec. 30, 2003

(51) Int. Cl. H03D 1/04; H04J 11/00

(52) U.S. Cl. 375/346; 370/210

(57) ABSTRACT

Various embodiments are described for an adaptive channel equalizer.

### CROSS-REFERENCE TO RELATED APPLICATIONS

This application is related to co-pending application Ser. No. 10/323,344, filed on Dec. 18, 2002, entitled “Adaptive Channel Estimation For Orthogonal Frequency Division Multiplexing Systems Or the Like.”

### BACKGROUND INFORMATION

Some communication systems may include features that may adapt to some types of changing conditions. For example, some systems allow a data transmission rate to be adjusted based upon a detected transmission condition. A need exists for an improved technique to allow a system to select or adapt a feature or parameter.

### BRIEF DESCRIPTION OF THE DRAWINGS

FIG. 1 is a diagram illustrating an example of a wireless communication system in accordance with an embodiment of the invention.

FIG. 2 is a block diagram illustrating a receiver including an adaptive equalizer according to an example embodiment.

FIG. 3 is a block diagram illustrating an embodiment of an averaging circuit according to an example embodiment.

FIG. 4 is a diagram illustrating examples of time domain averaging according to an embodiment.

### DETAILED DESCRIPTION

In the following detailed description, numerous specific details are set forth in order to provide a thorough understanding of the embodiments of the invention. It will be understood by those skilled in the art, however, that embodiments of the invention may be practiced without these specific details. In other instances, well-known methods, procedures and techniques have not been described in detail so as not to obscure the foregoing embodiments.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification discussions utilizing terms such as processing, computing, calculating, determining, or the like, refer to the action or processes of a computer or computing system, or similar electronic computing device, that manipulate or transform data represented as physical, such as electronic, quantities within the registers or memories of the computing system into other data similarly represented as physical quantities within the memories, registers or other such information storage, transmission or display devices of the computing system.

Embodiments of the present invention may include apparatuses for performing the operations herein. This apparatus may be specially constructed for the desired purposes, or it may comprise a general purpose computing device selectively activated or reconfigured by a program stored in the device. Such a program may be stored on a storage medium, such as, but is not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), flash memory, magnetic or optical cards, or any other type of media suitable for storing electronic instructions, and capable of being coupled to a system bus for a computing device.

The processes and displays presented herein are not inherently related to any particular computing device or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the invention as described herein.

In the following description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

It is worthy to note that any reference in the specification to “one embodiment” or “an embodiment” means in this context that a particular feature, structure, or characteristic described in connection with the embodiment may be included in at least one embodiment of the invention. The appearances of the phrase “in one embodiment” or “an embodiment” in various places in the specification do not necessarily refer to the same embodiment, but may be referring to different embodiments.

It should be understood that embodiments of the present invention may be used in a variety of applications. Although the present invention is not limited in this respect, the circuits disclosed herein may be used in many apparatuses such as in the transmitters and receivers of a radio system. Radio systems intended to be included within the scope of the present invention include, by way of example only, wireless local area networks (WLAN) devices and wireless wide area network (WWAN) devices including wireless network interface devices and network interface cards (NICs), base stations, access points (APs), gateways, bridges, hubs, cellular radiotelephone communication systems, satellite communication systems, two-way radio communication systems, Time Division Multiple Access (TDMA) systems, and the like, although the scope of the invention is not limited in this respect.

As used herein, the term packet may include a unit of data that may be routed or transmitted between nodes or stations or across a network. As used herein, the term packet may include frames, protocol data units or other units of data. A packet may include a group of bits, which may include one or more address fields, control fields and data, for example. Likewise, the term message may include any information, and may include packets, frames, protocol data units or other units of data, or portions thereof.

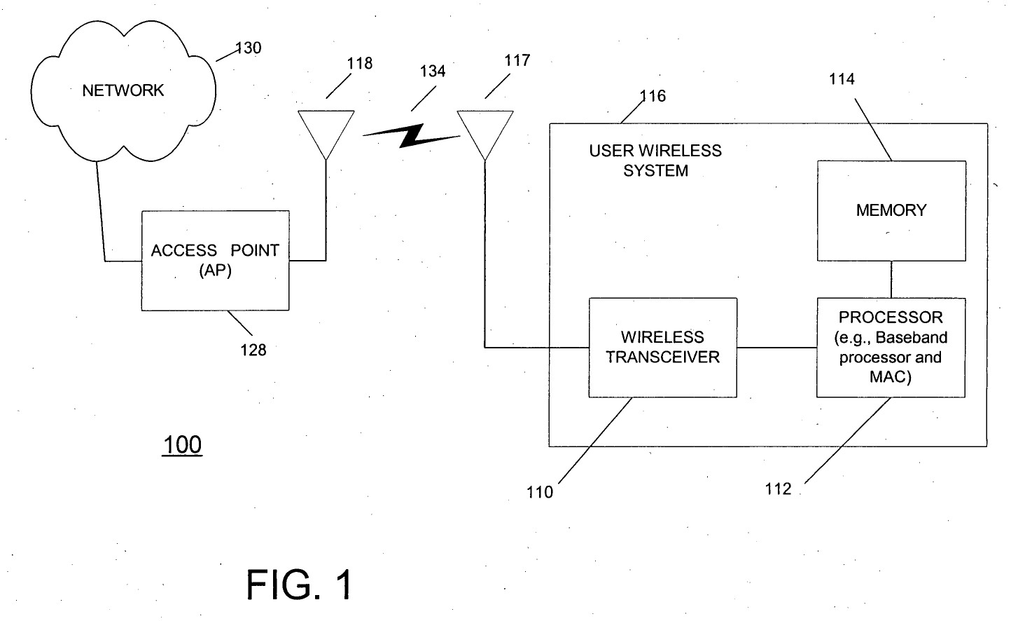

Referring to the Figures in which like numerals indicate like elements, FIG. 1 is a diagram illustrating an example of a wireless communication system in accordance with one embodiment of the invention. In the communications system 100 shown in FIG. 1, a user wireless system 116 may include a wireless transceiver 110 coupled to an antenna 117 and to a processor 112. Processor 112 in one embodiment may comprise a single processor, or alternatively may comprise a baseband processor and an applications processor, although the scope of the invention is not limited in this respect. According to one embodiment, processor 112 may include a baseband processor and Medium Access Control (MAC).

Processor 112 may couple to a memory 114 which may include volatile memory such as DRAM, non-volatile memory such as flash memory, or alternatively may include other types of storage such as a hard disk drive, although the scope of the invention is not limited in this respect. Some portion or all of memory 114 may be included on the same integrated circuit as processor 112, or alternatively some portion or all of memory 114 may be disposed on an integrated circuit or other medium, for example a hard disk drive, that is external to the integrated circuit of processor 112, although the scope of the invention is not limited in this respect. According to one embodiment, software may be provided in memory 114 to be executed by processor 112 to allow wireless system 116 to perform a variety of functions, which may include one or more functions described below.

Wireless system 116 may communicate with an access point (AP) 128 (or other wireless system) via wireless communication link 134, where access point 128 may include at least one antenna 118. Although not shown in FIG. 1, AP 128 may, for example, include a structure that is similar to wireless system 116, including a wireless transceiver, a processor, a memory, and software provided in memory to allow AP 128 to perform a variety of functions. In an example embodiment, wireless system 116 and AP 128 may be considered to be stations in a wireless communication system, such as a WLAN system.

Access point 128 may be coupled to network 130 so that wireless system 116 may communicate with network 130, including devices coupled to network 130, by communicating with access point 128 via wireless communication link 134. Network 130 may include a public network such as a telephone network or the Internet, or alternatively network 130 may include a private network such as an intranet, or a combination of a public and a private network, although the scope of the invention is not limited in this respect.

Communication between wireless system 116 and access point 128 may be implemented via a wireless local area network (WLAN), for example a network which may be compliant with an Institute of Electrical and Electronics Engineers (IEEE) standard such as IEEE 802.11a, IEEE 802.11b, IEEE 802.11g, IEEE 802.11n, IEEE 802.15, IEEE 802.16 and so on, although the scope of the invention is not limited in this respect. In addition, one or more aspects of the invention in some cases may be considered to be extensions to one or more current standards.

One or more aspects of the invention may be applied to single carrier systems where information may be transmitted over a single carrier. Alternatively, one or more aspects of the invention may be applied to multicarrier systems, such as an OFDM (Orthogonal Frequency Division Multiplexing) system for example, where information may be transmitted over multiple carriers or subcarriers, although the invention is not limited in this regard.

In another embodiment, communication between wireless system 116 and access point 128 may be implemented via a cellular communication network compliant with a 3GPP standard, although the scope of the invention is not limited in this respect.

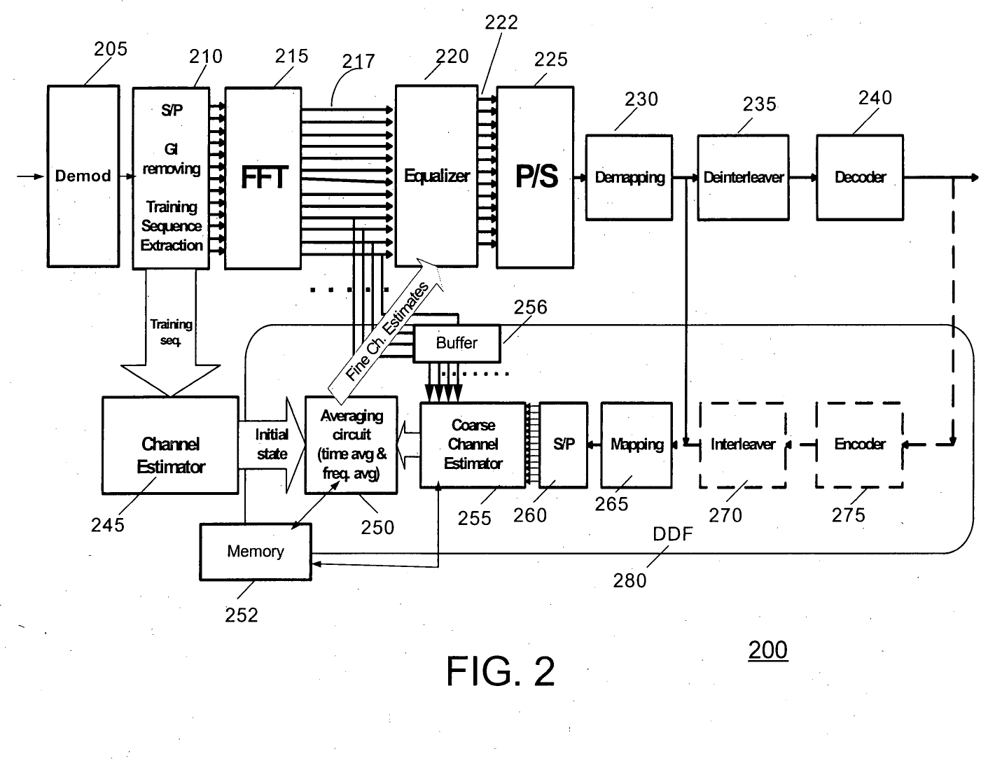

FIG. 2 is a block diagram illustrating a receiver including an adaptive equalizer according to an example embodiment. In an example embodiment, receiver 200 may be provided as part of a multicarrier system, such as an OFDM system for example where information may be provided on a plurality of subcarriers, although the invention is not limited thereto. An OFDM symbol may include, for example, a symbol transmitted simultaneously on each of the OFDM subcarriers during the OFDM symbol period. These individual symbols may be referred to as subcarrier symbols.

Some types of systems may embed channel estimation symbols (or training symbols) near the beginning of a packet to allow a receiver to estimate the channel transfer function (channel estimate) based on the training symbols.

FIG. 2 may be described with reference to the following:
Mₜ(n)—transmitted n-th subcarrier symbol (n=1, . . . , N_{ST}, set of subcarrier symbols);
Mᵣ—received time-domain OFDM symbol;
Mᵣ(n)—received n-th subcarrier symbol;
Mₑ(n)—equalized received n-th subcarrier symbol (e.g., which has been equalized by a coarse channel estimate or a fine channel estimate);
R(n)—replica of transmitted symbol Mₜ(n), which in some cases may equal Mᵣ(n);
Hᵢ(n)—coarse channel estimate based on the i-th received OFDM (or multicarrier) symbol on n-th subcarrier;
j—index of current OFDM symbol;
\overline{H}_{TD}^{j}(n)—time domain averaged channel estimate, which is a channel estimate on n-th subcarrier after time-domain averaging of N coarse channel estimates up to Hⱼ(n); (Bar over H indicates that some type of averaging may have been performed).
\overline{H}_{FD}^{j}(N)—frequency domain averaged channel estimate, which in one example embodiment, may be a channel estimate on n-th subcarrier after frequency-domain averaging (smoothing) of time domain averaged channel estimates \overline{H}_{TD}^{j}(l);
\overline{H}^{j}(n)—fine channel estimate on n-th subcarrier, which is used for equalization of next (j+1)-th OFDM symbol (in one embodiment fine channel estimate \overline{H}^{j}(n) may be equal to frequency domain averaged channel estimate \overline{H}_{FD}^{j}(n)).

Receiver 200 may receive incoming signals which are input to block 205. Block 205 may amplify, filter, downconvert and translate OFDM symbols received from antenna into time domain sample stream, which is then input to block 210.

Block 210 may perform a number of tasks, including removal of a guard interval of the OFDM symbol, extraction of a training sequence (training symbols), and performing a serial-to-parallel (S/P) conversion.

The received training symbols are provided to an initial channel estimator 245. Initial channel estimator 245 may use any known channel estimation technique to calculate an initial channel estimate \overline{H}⁰(n) for each subcarrier based on one or more received training symbols. For example, initial channel estimator 245 may compare the received training symbol (which may have been attenuated or distorted via the channel) to a stored copy of the transmitted training symbol. From this comparison (e.g., division), initial channel estimator 245 may calculate an initial channel estimate. In another example embodiment, initial channel estimator 245 may employ a least square (LS) algorithm with smoothing of the obtained channel estimates in the frequency domain. Smoothing window length L may be fixed (e.g., L=5) or chosen adaptively based on channel length estimate. This estimate of the channel may then be provided to an averaging circuit 250 where an averaging may or may not be performed on this initial channel transfer function estimate. The initial channel estimate may be stored in memory 252. The initial channel estimate may then be used to select coefficients for equalizer 220. In an example embodiment, the equalizer coefficients may be initially set to the inverse of the initial channel estimate, on a per subcarrier basis, although the invention is not limited thereto.

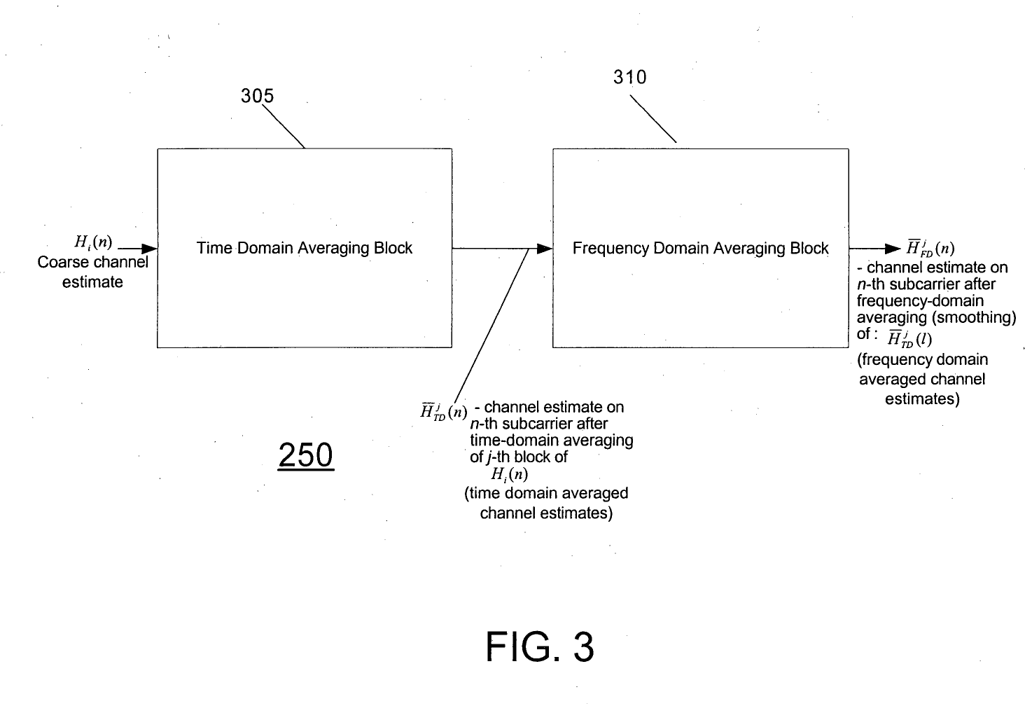

According to an example embodiment, initial channel estimator 245 may be provided as an adaptive channel estimator using frequency domain channel estimation and using time domain channel estimation shown in FIGS. 2 and 3 of application Ser. No. 10/323,344.

After an initial channel estimate \overline{H}⁰(n) is calculated by initial channel estimator 245 based on one or more received training symbols, OFDM (non-training) symbols are received at FFT 215, and coarse channel estimator 255 and averaging circuit 250 may be involved in calculating further channel estimates to be used in updating the equalizer coefficients, as described in more detail below.

The received time domain OFDM symbol Mᵣ from block 210 may be input to Fast Fourier Transform (FFT) 215 that recovers the N_{ST} OFDM subcarriers, and outputs subcarrier symbols Mᵣ(n) of the received OFDM symbol Mᵣ. The currently received OFDM symbol may include a subcarrier symbol for each subcarrier, which may be represented as an amplitude and phase or inphase (I) and quadrature (Q) components. These subcarrier symbol values Mᵣ(n) (e.g., including amplitude and phase for each subcarrier) are output via lines 217 to an equalizer 220. The received OFDM symbol Mᵣ(n) may be represented as the transmitted symbol multiplied by the channel transfer function H(n), as: Mᵣ(n)=Mₜ(n)H(n).

Equalizer 220 equalizes, or amplitude and phase compensates, the subcarrier symbols of the received OFDM symbol based on the equalizer coefficients, to compensate for the channel response (or channel transfer function). The equalizer coefficients may initially be set based on the initial channel estimate \overline{H}⁰(n), but later may be set based on updated coarse channel estimates provided by coarse channel estimator 255 and/or fine channel estimates output from averaging circuit 250. Equalized (compensated) subcarrier symbol values are output via lines 222 to a parallel-to-serial (P/S) block 225.

Inputs of equalizer 220 may include the received subcarrier symbols Mᵣ(n) via lines 217 (from current or j-th received OFDM symbol), and a set of fine channel estimates \overline{H}^{j-1}(n) (calculated from the previous or (j−1)-th OFDM symbol) for each subcarrier, output from averaging circuit 250. Output of equalizer 220 may be a set of equalized received subcarrier symbols Mₑ(n) of the current OFDM symbol. According to an example embodiment, equalizer 220 may generate equalized subcarrier symbols Mₑ(n) as the received OFDM symbol Mᵣ(n) divided by the current fine channel estimate \overline{H}^{j-1}(n), for each subcarrier, according to the following equation:

$${M}_{e} ( n ) = \frac{{M}_{r} ( n )}{{\overline{H}}^{j - 1} ( n )}$$

According to an example embodiment, the fine channel estimate \overline{H}ⁱ(n), may initially be set to the initial channel estimate \overline{H}⁰(n). However, the channel transfer function in some cases may change within a packet (during transmission of a packet) due to time-variant fluctuation of the frequency-selective channel caused, for example, by Doppler effect.

As noted above, the equalizer 220 may divide a received OFDM symbol Mᵣ(n) by the fine channel estimate \overline{H}ⁱ(n), for each subcarrier n, to calculate the equalized OFDM symbol output from the equalizer 220 onto lines 222. In other words, according to an example embodiment, the equalizer coefficients for equalizer 220 may be the inverse of the fine (averaged) channel estimates.

Demapping block 230 may convert the equalized received OFDM symbol (plurality of equalized received subcarrier symbols Mₑ(n)) to a group of bits. Deinterleaver 235 deinterleaves the bits, while decoder 240 decodes the deinterleaved information. Decoder 240 may be any type of decoder, such as a Viterbi decoder, although the invention is not limited thereto. The decoded information may then be output to be processed.

According to an example embodiment, equalizer 220 may be an adaptive equalizer to adapt to changing conditions, such as a changing channel transfer function (or channel estimate) due to multi-path frequency-selective fading, which in some cases may change even during or within a packet. Therefore, the adaptive equalizer may include a decision directed feedback (DDF) loop, which is shown as all or part of block 280. DDF loop 280 may include, for example, blocks 275, 270, 265 and 260. In an embodiment, the adaptive equalizer may also be considered to include blocks 250 and 255.

Blocks within DDF loop 280 may generate a replica R(n) of the j-th transmitted OFDM symbol Mₜ(n), for each subcarrier n. These generated replicas may be used to generate updated channel estimates to equalizer 220. DDF loop 280 may include an encoder 275 to encode information output by decoder 240, an interleaver 270 to interleave the encoded information, a mapping block 265 to map the information to one or more OFDM symbols. In another embodiment, DDF loop 280 may omit encoder 275 and interleaver 270 to simplify the DDF loop 280. However, the use of encoder 275 and interleaver 270 in DDF 280 may allow the generation of a more accurate replica R(n) of a transmitted symbol Mₜ(n).

The output of mapping block 265 is a replica R(n) of the j-th transmitted OFDM symbol Mₜ(n), for each subcarrier n. In many cases, the replica R(n) may be equal to the transmitted OFDM symbol Mₜ(n), although this may not always be the case. This may provide the decision directed feedback that may in some cases allow the equalizer 220 to be updated or adapt based on a changing channel transfer function.

The replica R(n) output from mapping block 265 is passed through a serial-to-parallel (S/P) block 260 to output the subcarrier symbols of the replica R(n) to a coarse channel estimator 255.

In one embodiment coarse channel estimator 255 may receive as inputs: the replica R(n) from S/P 260, and the received subcarrier symbols Mᵣ(n) via lines 217 (from current or j-th received OFDM symbol) for each subcarrier n, and may calculate coarse channel estimates. In another embodiment the received subcarrier symbols Mᵣ(n) may be stored in buffer 256 for the time equals the time of replica R(n) generated by DDF loop 280.

According to an example embodiment, coarse channel estimates Hᵢ(n) may be calculated by block 255 as the received symbol Mᵣ(n) divided by the replica R(n) of the corresponding transmitted symbol, for each subcarrier n, although the invention is not limited thereto:

$${H}_{i} ( n ) = \frac{{M}_{r} ( n )}{R ( n )}$$

As noted, the adaptive equalizer may include a coarse channel estimator 255 which may generate coarse (or unaveraged) channel estimates, and an averaging circuit 250 which generates fine (or averaged) channel estimates.

FIG. 3 is a block diagram illustrating an embodiment of an averaging circuit according to an example embodiment. Averaging may advantageously be performed on the coarse channel estimates to, at least in some cases, assist in decreasing noise and/or distortion.

Referring to FIG. 3, averaging circuit 250 may include a time domain averaging block 305 and/or a frequency domain averaging block 310. For example, in one embodiment, averaging circuit 250 may include only a time domain averaging block or only a frequency domain averaging block 310. In another embodiment, averaging circuit 250 may advantageously include both a time domain averaging block 305 and a frequency domain averaging block 310.

Referring to FIG. 3, time domain averaging block 305 may generate time domain averaged channel estimates \overline{H}_{TD}^{j}(n) for each subcarrier n by averaging N coarse (unaveraged) channel estimates Hᵢ(n) for each of the N_{ST} subcarriers. Time domain averaging may be performed a number of different ways. For example, the time domain averaged estimate may be generated as the average of the current coarse channel estimate plus the previous N−1 coarse channel estimates (e.g., corresponding to the previous N−1 OFDM received symbols), for each subcarrier. These previous N−1 coarse channel estimates may be stored in memory 252.

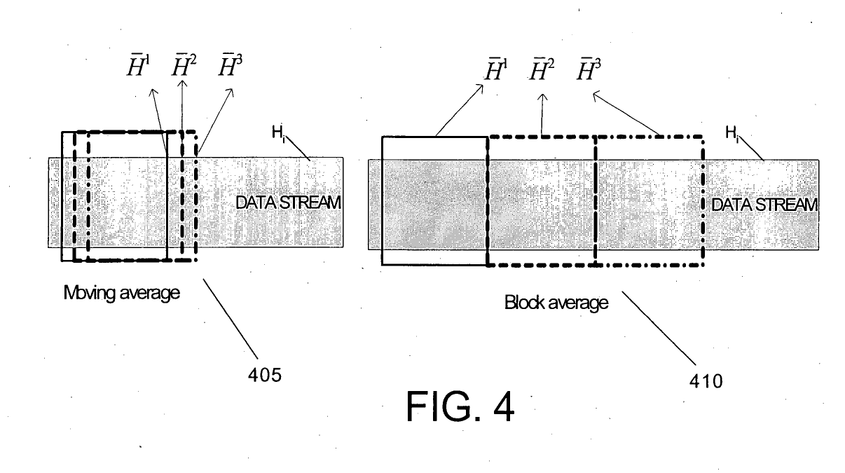

Also, time domain averaging may be performed a number of different ways, such as either as a moving average or a block average, as examples. FIG. 4 is a diagram illustrating examples of a moving average and a block average for time domain averaging of coarse channel estimates Hᵢ(n).

Time Domain Averaging—Moving Average:

Referring to FIG. 4, as shown by 405, a moving average may involve averaging of the N coarse channel estimates within the window. After the next coarse channel estimate is calculated, the window may move forward one coarse channel estimate, for example. The moving average may be represented generally as:

$${\overline{H}}_{T D}^{j} ( n ) = {\sum }_{k = 0}^{N - 1} {w}_{k} \cdot {H}_{j - k} ( n ) \qquad ( eqn . 1.1 )$$

where N is the size of the moving window, and wₖ are weighting coefficients. In case of weighting with uniform coefficients, eqn. 1.1 can be simplified as:

$${\overline{H}}_{T D}^{j} ( n ) = {\overline{H}}_{T D}^{j - 1} ( n ) + \frac{1}{N} ( {H}_{j} ( n ) - {H}_{j - N} ( n ) ) \qquad ( eqn . 1.2 )$$

Time Domain Averaging—Block Averaging:

Time domain block averaging may be performed according to the following equation, for example:

$${\overline{H}}_{T D}^{p} ( n ) = \frac{1}{N} {\sum }_{k = 0}^{N} {H}_{( p - 1 ) \cdot N + k} ( n ) , \qquad ( eqn . 1.3 )$$

where N is block size. \overline{H}_{TD}^{p}(n) may be considered to be an arithmetic mean of N coarse channel estimates Hᵢ(n) of p-th block. In this case index of the last OFDM symbol of current (p-th) block may be represented as j=p·N.

Time domain block averaging may be also performed step-by-step as a cumulative sum of incoming coarse channel estimates Hᵢ(n), using the following example procedure:

$${\overline{H}}_{T D}^{p , k} ( n ) = {\overline{H}}_{TD}^{p , k - 1} ( n ) + {w}_{k} \cdot {H}_{( p - 1 ) \cdot N + k} ( n ) , \\ for k = 1 , … , N \qquad ( eqn . 1.4 )$$

When the current block of N symbols finishes, the

$${\overline{H}}_{T D}^{p} ( n ) = {\overline{H}}_{T D}^{p , N} ( n )$$

may be output to frequency domain averaging block 310 and all

$${\overline{H}}_{T D}^{p + 1 , 0} ( n )$$

are set to zero for new accumulation cycle. In this case it is not needed to store N−1 previous coarse channel estimates Hᵢ(n) in memory 252.

For both moving average and block averaging types of time domain average, set of weights wₖ may be determined by Doppler spread for the channel. In one embodiment, weights wₖ may be pre-calculated by using a-priory information about channel or propagation environment, or information that is periodically updated by current Doppler spread estimation for the channel. In one example embodiment, weights wₖ may be set as

$${w}_{k} = \frac{1}{N}$$

and N=10, as an example embodiment.
Frequency Domain Averaging:

Frequency domain averaging may be performed by frequency domain averaging block 310 in FIG. 3. Frequency domain averaging block 310 may generate fine channel estimates equal to the frequency domain averaged channel estimates (\overline{H}^{j}(n)=\overline{H}_{FD}^{j}(n)) for each subcarrier by frequency domain averaging the time domain averaged channel estimates \overline{H}_{TD}^{j}(n). As noted above, the equalizer coefficients may be set to the inverse of the fine channel estimates \overline{H}^{j}(n), according to an example embodiment.

The frequency domain averaged channel estimate \overline{H}_{FD}^{j}(n) for n-th subcarrier may be produced by windowing (or taking the average over the window) of L subcarriers of the time domain averaged channel estimate \overline{H}_{TD}^{j}(l). According to an example embodiment, the averaging may be performed across one or more adjacent subcarriers. For example, the frequency domain averaged subcarrier estimate \overline{H}_{FD}^{j}(n) for n=4 (i.e., for subcarrier 4) may be calculated as the average of subcarriers 2, 3, 4, 5 and 6 (this would be average of values for subcarrier 4, and the two adjacent subcarriers on either side) of the time domain averaged channel estimates \overline{H}_{TD}^{j}(l). This example would use a window size of L=5 (the subcarrier of interest, plus two adjacent subcarriers on either side to be included in the average, in this example). This is merely an example, and the invention is not limited thereto.

According to an embodiment, frequency domain averaging may be performed once per one block in accordance with following equation, although the invention is not limited thereto:

$${\overline{H}}_{F D}^{j} ( n ) = {\sum }_{l = - \frac{L - 1}{2}}^{\frac{L - 1}{2}} h ( l ) \cdot {\overline{H}}_{T D}^{j} ( n - l )$$

In an example embodiment, frequency domain window length L and frequency domain window coefficients h(l) may be determined from information about channel transfer function or channel response profile. In one embodiment, these parameters may be set based on initial channel estimate processing of the long training sequence as provided in IEEE 802.11a. A set of fine channel estimates \overline{H}^{j}(n)=\overline{H}_{FD}^{j}(n), obtained by processing j-th OFDM symbol, may then be used for the equalization of the next (j+1)-th received OFDM symbol.

According to an example embodiment, the averaging circuit 250 may be provided an adaptive channel estimator using frequency domain channel estimation and using time domain channel estimation shown in FIGS. 2 and 3 of application Ser. No. 10/323,344.

While certain features of the embodiments of the invention have been illustrated as described herein, many modifications, substitutions, changes and equivalents will now occur to those skilled in the art. It is, therefore, to be understood that the appended claims are intended to cover all such modifications and changes as fall within the true spirit of the embodiments of the invention.

1. An apparatus comprising:
an averaging circuit adapted to provide an averaged channel estimate by performing a time domain averaging and frequency domain averaging on one or more received inputs; and
an equalizer to equalize a received multicarrier symbol based on the averaged channel estimate.

2. The apparatus of claim 1 wherein the averaging circuit is adapted to provide an averaged channel estimate by performing a time domain averaging and frequency domain averaging on one or more received channel estimates.

3. The apparatus of claim 1 wherein the averaging circuit comprises:
a time domain averaging block adapted to perform time domain averaging on a plurality of received channel estimates to generate a time domain averaged channel estimate on a per subcarrier basis; and
a frequency domain averaging block adapted to perform frequency domain averaging on a received time domain averaged channel estimate.

4. The apparatus of claim 3 wherein the frequency domain averaging block generates frequency domain averaged channel estimates that are used to update coefficients of the equalizer.

5. The apparatus of claim 3 wherein the time domain averaging block is adapted to perform time domain averaging on a plurality of received channel estimates to generate a time domain averaged channel estimate on a per subcarrier basis using a moving average.

6. The apparatus of claim 3 wherein the time domain averaging block is adapted to perform time domain averaging on a plurality of received channel estimates to generate a time domain averaged channel estimate on a per subcarrier basis using block averaging.

7. The apparatus of claim 1 and further comprising a coarse channel estimator to generate a coarse channel estimate to be input to the averaging circuit.

8. The apparatus of claim 7 wherein the coarse channel estimator is adapted to generate a coarse channel estimate as the received symbol divided by a replica of a transmitted symbol, per subcarrier.

9. The apparatus of claim 1 wherein the equalizer comprises an adaptive equalizer.

10. The apparatus of claim 1 wherein the multicarrier symbol comprises an OFDM symbol.

11. An apparatus comprising:
an equalizer to equalize a received symbol based on a fine channel estimate;
a mapping block to provide a replica of a transmitted symbol;
a coarse channel estimator to receive a symbol replica from the mapping block and a corresponding received symbol, the coarse channel estimator to generate a coarse channel estimate;
an averaging circuit adapted to perform time domain averaging on a plurality of coarse channel estimates to generate a time domain averaged channel estimate, and to perform frequency domain averaging on the time domain averaged channel estimate to generate the fine channel estimate.

12. The apparatus of claim 11 wherein the averaging circuit comprises a time domain averaging block and a frequency domain averaging block.

13. The apparatus of claim 11 wherein the received symbol comprises a multicarrier symbol, and the replica symbol comprises a replica of a corresponding transmitted multicarrier symbol.

14. The apparatus of claim 13 wherein the received multicarrier symbol comprises an OFDM symbol.

15. A method comprising:
performing a time domain averaging on one or more received inputs to generate a time domain averaged channel estimate on a per subcarrier basis;
performing a frequency domain averaging on the time domain averaged channel estimate to generate a fine channel estimate; and
updating equalizer coefficients based upon the fine channel estimate.

16. The method of claim 15 wherein the performing a time domain averaging comprises:
generating a coarse channel estimate based on a received multicarrier symbol and a generated replica of the corresponding transmitted multicarrier symbol; and
performing a time domain averaging on a plurality of coarse channel estimates on a per subcarrier basis to generate a time domain averaged channel estimate.

17. The method of claim 16 wherein the generating a coarse channel estimate comprises:
generating a replica of a transmitted multicarrier symbol; and
generating a coarse channel estimate by dividing a received multicarrier symbol by the generated replica of the corresponding transmitted multicarrier symbol.

18. A method comprising:
calculating an initial channel estimate based upon one or more received training symbols;
setting equalizer coefficients based upon the initial channel estimate;
performing both time domain averaging and frequency domain averaging on a subsequent calculated channel estimate to generate an averaged channel estimate; and
updating the equalizer coefficients based upon the averaged channel estimate.
